(19) United States
(12) Patent Application Publication
(10) Pub. No.: US 2016/0343778 A1
(43) Pub. Date: Nov. 24, 2016

(54) SEVERABLE ORGANIC LIGHT-EMITTING DIODE MODULE

(71) Applicant: WiseChip Semiconductor Inc., Miaoli County (TW)

(72) Inventors: Chien-Le LI, Miaoli County (TW); Yung-Cheng TSAI, Miaoli County (TW); Chien-Hsun CHEN, Miaoli County (TW)

(21) Appl. No.: 14/716,146

(22) Filed: May 19, 2015

(51) Int. Cl. H01L 27/32; H01L 51/52

(52) U.S. Cl. CPC H01L 27/3204; H01L 51/5206; H01L 51/5221; H01L 27/3202

(57) ABSTRACT

A severable organic light-emitting diode module includes a substrate, a first electrode located on the substrate, an organic light-emitting element layer, an electric connection element, an insulation wall and a second electrode. The organic light-emitting element layer is located on the first electrode and includes a bottom surface, a top surface and a through hole run through the bottom surface and the top surface. The electric connection element is located in the through hole and has a bottom portion in contact with the first electrode and a top portion extended over the top surface. The insulation wall is located between the electric connection element and the organic light-emitting element layer. The second electrode is located on the top surface. The second electrode and the top portion of the electric connection element are located at an electric connection side higher than the top surface of the organic light-emitting element layer.

### FIELD OF THE INVENTION

The present invention relates to a light-emitting element and particularly to a severable organic light-emitting diode module.

### BACKGROUND OF THE INVENTION

Organic light-emitting diode (OLED in short hereinafter) has many advantages, such as providing self-generating light, flexible, power saving and the like, hence has been widely used in lighting and display applications. Many companies and institutions have devoted a great amount of resources and manpower to do research and improvement on OLED-related projects.

For instance, U.S. patent publication No. 20140097424 A1 discloses a flat surface light emission device which is located on a transparent substrate. The flat surface light emission device includes an anode, an organic layer, a cathode, an anode input portion, a cathode input portion, an ancillary anode and an ancillary cathode. The anode input portion, the ancillary anode, the cathode input portion and the ancillary cathode are located at one side of the transparent substrate to form electrical connection respectively with the anode and the cathode.

Due to the anode and the cathode have to rely on other electric structures (i.e. the anode input portion, the ancillary anode, the cathode input portion) that are extended to outer edges of the organic layer to form electric connection with external conductive wires, once fabrication is finished the usable area of the OLED element is fixed (i.e. the area of light emitting layer surrounded by the electric structures). As a result, the size of the OLED element cannot be changed flexibly. Trying to cut the OLED element at a desired size, the cutoff portion does not have electric connection structure, hence becomes useless. This is troublesome in applications. Moreover, in the event that material defects or other flaws happened in a portion of the OLED element that cause problems in light emission, the flat surface light emission device becomes a defected product and is useless.

### SUMMARY OF THE INVENTION

The primary object of the present invention is to solve the problem of the conventional OLED elements of requiring electric conductive structure at the edge of light emitting layer that results in not severable of the OLED elements and not changeable of the size thereof.

To achieve the foregoing object the present invention provides a severable OLED module that includes a substrate and a plurality of OLED units located on the substrate. Each OLED unit includes a first electrode, an organic light-emitting element layer, an electric connection element, an insulation wall and a second electrode. The first electrode is located on the substrate and includes a light permeable zone and an electric conductive zone abutting the light permeable zone. The organic light-emitting element layer is located on the first electrode and includes a bottom surface in contact with the first electrode, a top surface remote from the first electrode, and a through hole which runs through the bottom surface and the top surface and also corresponds to the electric conductive zone. The electric connection element is located in the through hole and has a bottom portion in contact with the electric conductive zone and a top portion extended axially from the bottom portion in parallel with the through hole and protruded at least over the top surface. The insulation wall is located between the electric connection element and the organic light-emitting element layer. The second electrode is located on the top surface. The second electrode and the top portion of the electric connection element are located at an electric connection side higher than the top surface of the organic light-emitting element layer.

Thus, with the through hole run through the organic light-emitting element layer and the electric connection element located directly located in the through hole, the first electrode and the second electrode of each OLED unit can be positioned at the electric connection side higher than the top surface of the organic light-emitting element layer, hence in the event that severing the OLED units is required each OLED unit can still keep the electric connection element and the second electrode, and external conductive wires can be disposed at the electric connection side to form electric connection with the electric connection element and the second electrode to make it ready for use. As a result, the invention can provide advantage of severable size. In addition, in the event that a portion of the OLED units malfunctions the defected portion can be removed individually while the rest OLED units remain usable, thus unnecessary waste can be prevented.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1A is a schematic view of the structure of an embodiment of the invention.

FIG. 1B is a top view of a first electrode of an embodiment of the invention.

FIG. 2 is a top view of an embodiment of the invention.

### DETAILED DESCRIPTION OF THE PREFERRED EMBODIMENTS

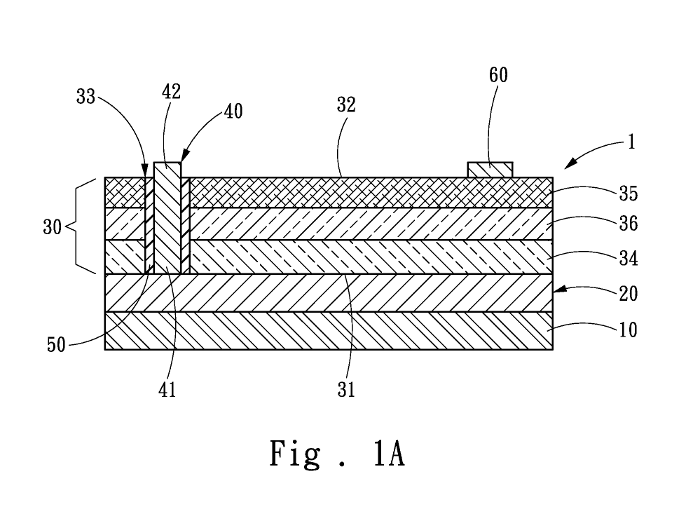

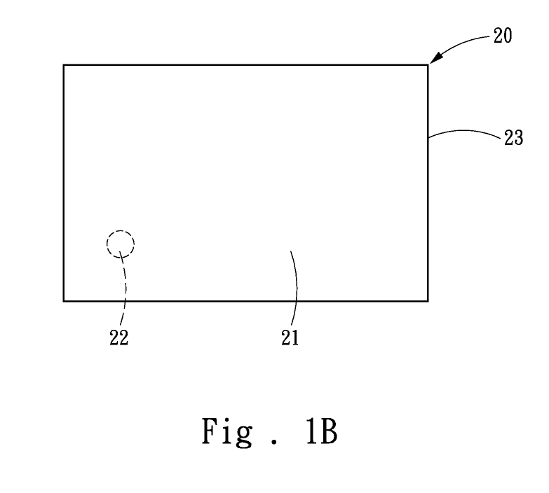

Please refer to FIGS. 1A and 1B for an embodiment of the invention. The invention is a severable OLED module that includes a substrate 10 and a plurality of OLED units 1 on the substrate 10. Each OLED unit 1 includes a first electrode 20, an organic light-emitting element layer 30, an electric connection element 40, an insulation wall 50 and a second electrode 60.

The substrate 10 can be light permeable or light impermeable, and can be made from glass, plastics, silicon, grapheme, gallium arsenide (GaAs), Gallium nitride (GaN) or silicon carbide (SiC). The first electrode 20 is located on the substrate 10 and can be an anode or a cathode. When the first electrode 20 is the anode, the second electrode 60 is the cathode, or vice versa. In this embodiment the first electrode 20 is the anode, while the second electrode 60 is the cathode.

The first electrode 20 can be made of a metal film, a metal compound film, a ceramic material or a macro molecule conductive material. The metal film can be made of gold (Au), silver (Ag), platinum (Pt), copper (Cu), aluminum (Al), chrome (Cr), palladium (Pd) or rhodium (Rh). The metal compound film is preferably formed at a thickness less than 250 nm and can be metal oxide, metal nitride or metal fluoride, such as Indium Tin Oxide (ITO in short), Indium Gallium Zinc Oxide (IGZO in short) that are Indium contained metal oxides, or metal oxides without Indium such as alumina, zinc oxide or the like. The ceramic material can be nano carbon tubes or grapheme. The macro molecule conductive material can be PEDOT:PSS or other electric conductive macro molecules. The first electrode 20 includes a light permeable zone 21, an electric conductive zone 22 and a rim 23. The light permeable zone 21 is adjacent to the electric conductive zone 22. In this embodiment the electric conductive zone 22 is circular and surrounded by the light permeable zone 21 and remote from the rim 23. However, the electric conductive zone 22 is not limited to the circular shape, other shapes also can be formed as long as they are remote from the rim 23 without in contact therewith.

The organic light-emitting element layer 30 is located on the first electrode 20 and includes a bottom surface 31, a top surface 32 and a through hole 33. The bottom surface 31 is in contact with the first electrode 20. The top surface 32 is located at one side opposing the bottom surface 31 and remote from the first electrode 20. The through hole 33 runs through the bottom surface 31 and the top surface 32, and corresponds to the electric conductive zone 22 of the first electrode 20. In this embodiment the organic light-emitting element layer 30 further includes an electron hole transmission layer 34, an electron transmission layer 35 and a light emitting layer 36. The electron hole transmission layer 34 is connected to the first electrode 20, and can be made from an adulteratable transmission material of high electron hole mobility, such as an organic compound or organic metal compound. The organic compound can be aromatic amine or benzene functional group such as Dipyrazino [2,3-f:2′,3′-h]quinoxaline 2,3,6,7,10,11-hexacarbonitrile (HAT-CN), N,N′-Di(1-naphthyl)-N,N′-diphenyl-(1,1′-biphenyl)-4,4′-diamine (NPB) or Copper Phthalocyanine (CuPc). The electron transmission layer 35 is located at one side of the electron hole transmission layer 34 remote from the first electrode 20 and connected to the second electrode 60, and can be made from an adulteratable transmission material of high electron mobility, and can be an organic compound or an organic metal compound. The organic compound can be carbon-rich functional groups with mixed rings, such as aromatic amine, or benzene functional group and Silicon or Nitrogen. The organic metal compound can be Tris(8-hydroxyquinolinato) aluminium (Alq3) or BeBq(2). The light emitting layer 36 is located between the electron hole transmission layer 34 and the electron transmission layer 35. In this embodiment when the first electrode 20 is the cathode and the second electrode 60 is the anode, the electron transmission later 35 is connected to the first electrode 20, and the electron hole transmission layer 34 is connected to the second electrode 60. The light emitting layer 36 can be a single film or multi-film structure.

The electric connection element 40 is located in the through hole 33 and has a bottom portion 41 in contact with the electric conductive zone 22 and a top portion 42 extended axially from the bottom portion 41 in parallel with the through hole 33 and protruded at least over the top surface 32. The electric connection element 40 can be made of aluminum (Al), molybdenum (Mo), gold (Au), silver (Ag), platinum (Pt), copper (Cu), aluminum (al), chrome (Cr), palladium (Pd) or Rhodium (Rh). The insulation wall 50 is located between the electric connection element 40 and the organic light-emitting element layer 30, and in this embodiment, it is located in the through hole 33 to surround the electric connection element 40, and can be made from insulation material contained organic macro molecule polymers, such as resin, Polyethylene Terephthalate (PET), Polyimide (PI), Epoxy, Polymethylmethacrylate (PMMA) or Acrylic. The insulation wall 50 isolates electrically the electric connection element 40 and the organic light-emitting element layer 30.

The second electrode 60 is located on the top surface 32 of the organic light-emitting element layer 30 and connected to the electron transmission layer 35, and can be made of a metal film, a metal compound film or a non-metallic material. The metal film can be made of gold (Au), silver (Ag), platinum (Pt), copper (Cu), aluminum (Al), chrome (Cr), palladium (Pd) or rhodium (Rh). The metal compound film is preferably formed at a thickness less than 250 nm, and can be metal oxide, metal nitride or metal fluoride, such as Indium Tin Oxide (ITO), Indium Gallium Zinc Oxide (IGZO) or the like that is Indium contained metal oxide, or metal oxides without Indium such as alumina, zinc oxide or the like. The non-metallic material can be nano carbon tubes, grapheme, nano silver or macro molecule conductive material (such as PEDOT:PSS) or the like. The second electrode 60 and the top portion 42 of the electric connection element 40 are located at an electric connection side and protruded higher than the top surface 32 of the organic light-emitting element layer 30. In this invention the OLED unit 1 can be upward light emission or downward light emission depending on whether the substrate 10, the first electrode 20 and the second electrode 60 are light permeable. In this invention at least one of the first electrode 20 and the second electrode 60 is light permeable.

The organic light-emitting element layer 30, through the electric connection element 40, can extend an electric contact position of the first electrode 20 to a same side of the organic light-emitting element layer 30 where the second electrode 60 is located so that electric wiring does not necessary be located at the edge; and through a power circuit an external bias voltage can be provided to the electron hole transmission layer 34 and the electron transmission layer 35 via the first electrode 20 and the second electrode 60, thereby the electron hole transmission layer 34 and the electron transmission layer 35 can generate respectively a plurality of electron holes and electrons to enter the light emitting layer 36 to release energy in a visible light form.

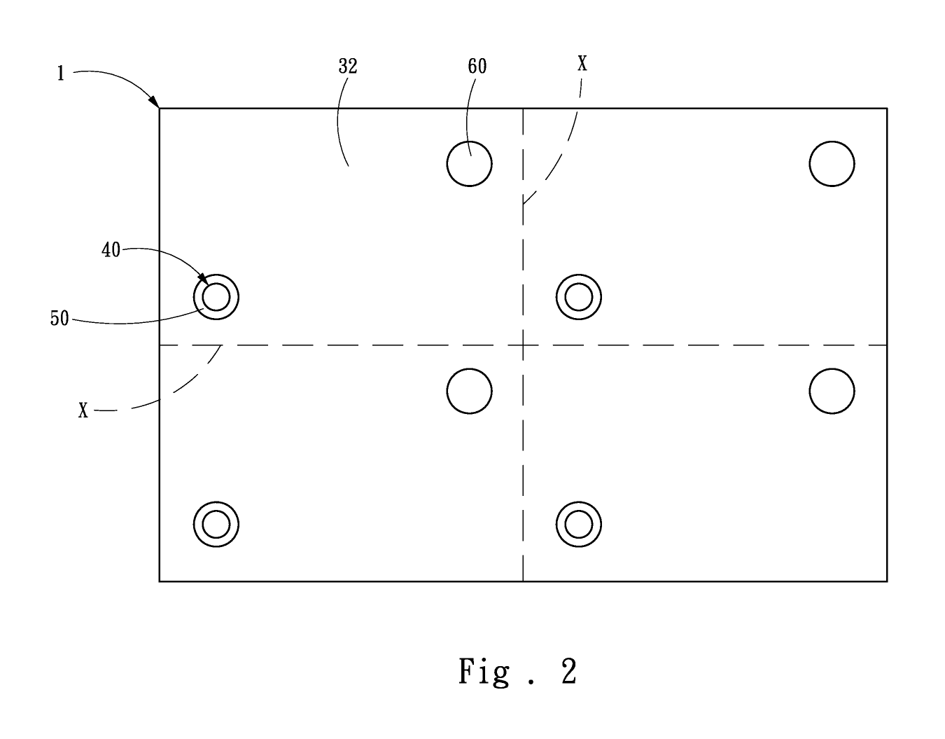

Please referring to FIG. 2 for a top view of an embodiment of the invention. In this embodiment four organic OLED units 1 are provided. By directly locating the electric connection element in the through hole each OLED unit 1 has the first electrode and the second electrode with the electric connection side at an elevation higher than the top surface of the organic light-emitting element layer, hence can be severed as desired. For instance, severed via a cutting line X can get a single OLED unit 1 or a cluster consisting of a plurality of OLED units 1, therefore the size of the OLED module can be changed easily. Moreover, in the event that a certain OLED unit 1 in the OLED module malfunctions, the flawed one can be removed individually without discarding the entire OLED module as the conventional techniques do, hence the concerns of waste and higher cost that might otherwise occur can be avoided.

As a conclusion, the invention, with the through hole run through the organic light-emitting element layer, the electric connection element can be directly located in the through hole to position the electric connection side of the first electrode and the second electrode higher than the top surface of the organic light-emitting element layer. Hence the OLED units can be severed as desired, and each severed OLED unit still maintains the electric connection element and the second electrode, and the external conductive wires can be connected to the electric connection side to form electric connection with the electric connection element and the second electrode. As a result, the severed OLED unit is still functional, hence the size of the OLED module can be severed and adjusted as desired. It provides significant improvements over the conventional techniques.

While the preferred embodiments of the invention have been set forth for the purpose of disclosure, they are not the limitation of the invention, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A severable organic light-emitting diode (OLED) module, comprising:
a substrate; and
a plurality of OLED units located on the substrate, each OLED unit including:
a first electrode which is located on the substrate and includes a light permeable zone and an electric conductive zone abutting the light permeable zone;
an organic light-emitting element layer which is located on the first electrode and includes a bottom surface in contact with the first electrode, a top surface remote from the first electrode and a through hole run through the bottom surface and the top surface, the through hole corresponding to the electric connective zone;
an electric connection element which is located in the through hole and includes a bottom portion in contact with the electric conductive zone and a top portion extended axially from the bottom portion in parallel with the through hole, the top portion being protruded at least over the top surface;
an insulation wall located between the electric connection element and the organic light-emitting element layer; and
a second electrode located on the top surface, the second electrode and the top portion of the electric connection element being located at an electric connection side higher than the top surface of the organic light-emitting element layer.

2. The severable organic light-emitting diode module of claim 1, wherein the first electrode is an anode, the second electrode is a cathode and the organic light-emitting element layer includes an electron hole transmission layer connected to the first electrode and an electron transmission layer remote from the first electrode and connected to the second electrode.

3. The severable organic light-emitting diode module of claim 1, wherein the first electrode is a cathode, the second electrode is an anode and the organic light-emitting element layer includes an electron transmission layer connected to the first electrode and an electron hole transmission layer remote from the first electrode and connected to the second electrode.

4. The severable organic light-emitting diode module of claim 2, wherein the organic light-emitting element layer further includes a light emitting layer located between the electron hole transmission layer and the electron transmission layer.

5. The severable organic light-emitting diode module of claim 3, wherein the organic light-emitting element layer further includes a light emitting layer located between the electron hole transmission layer and the electron transmission layer.

6. The severable organic light-emitting diode module of claim 1, wherein the first electrode further includes a rim, the electric conductive zone being surrounded by the light permeable zone and remote from the rim.

7. The severable organic light-emitting diode module of claim 1, wherein the substrate is selected from the group consisting of glass, plastics, silicon, grapheme, gallium arsenide (GaAs), gallium nitride (GaN) and silicon carbide (SiC).
